(19) United States
(12) Patent Application Publication
(10) Pub. No.: US 2026/0164985 A1
(43) Pub. Date: Jun. 11, 2026

(54) Display Apparatus

(71) Applicant: LG Display Co., Ltd., Seoul (KR)

(72) Inventors: Goeun Lim, Mokpo-si (KR); Heesu Byeon, Paju-si (KR)

(21) Appl. No.: 19/349,924

(22) Filed: Oct. 3, 2025

(30) Foreign Application Priority Data
Dec. 11, 2024 (KR) 10-2024-0184162

(51) Int. Cl. H10K 59/80; H10K 59/38; H10K 102/00

(52) U.S. Cl. CPC H10K 59/80515; H10K 59/38; H10K 59/80517; H10K 59/873; H10K 59/878; H10K 2102/351

(57) ABSTRACT

A display apparatus may include a first substrate including a plurality of sub-pixels, a plurality of light-emitting elements disposed respectively in the plurality of sub-pixels, and a reflective structure disposed between adjacent light-emitting elements, and each of the plurality of light-emitting elements may include a spherical structure.

### CROSS REFERENCE TO RELATED APPLICATION

The present application claims priority to Republic of Korea Patent Application No. 10-2024-0184162, filed on December 11, 2024, which is hereby incorporated by reference in its entirety.

### BACKGROUND

This disclosure relates to a display apparatus for displaying images.

Display apparatuses are applied to various electronic devices such as televisions (TVs), mobile phones, laptops, and tablets. To this end, a range of research have been conducted to develop display apparatuses that are thinner, lighter, and have lower power consumption.

As the demand for head mounted displays (HMDs) including display apparatuses has increased recently, research on them has also increased. The head-mounted display is an image display apparatus employing a device in the form of eyeglasses or a helmet to form a focus close to a user's eyes.

The head-mounted display can implement virtual reality (VR) or augmented reality (AR). The head-mounted display has the advantage of providing a user with a high level of immersion into the screen, making a 1-inch image look as if it is as large as 60-inch image. For this purpose, the head-mounted display requires a small display apparatus with ultra-high resolution to be applied therein.

The description provided in the background section should not be assumed to be prior art merely because it is mentioned in or associated with the background section. The background section may include information that describes one or more aspects of the subject technology.

### SUMMARY

As users' demand for high-quality images has increased recently, research is being conducted on display apparatuses with high resolution and high brightness.

Meanwhile, an organic light-emitting display apparatus may have a light-emitting layer configured with and including an organic material that emits white light. As the light-emitting layer emits white light, each sub-pixel may include a color filter to emit light of a different color to the outside.

As an example, in the case where white light generated from a light-emitting layer is emitted to the outside through a color filter, there may occur a problem of reducing the light brightness.

As another example, there may occur a problem of reducing color reproducibility of light emitted to the outside through a color filter.

To overcome the above-described drawbacks, the inventors of the present disclosure have invented, through various experiments, a display apparatus capable of increasing the brightness of light emitted from a display panel.

An object to be accomplished according to an embodiment of the present disclosure is to provide a display apparatus with an improved brightness realized by increasing a light-emitting surface area.

Additionally, another object to be accomplished according to an embodiment of the present disclosure is to provide a display apparatus including a configuration capable of preventing color mixing between neighboring sub-pixels and of increasing the extraction efficiency of light emitted from a plurality of sub-pixels.

Additionally, yet another object to be accomplished according to an embodiment of the present disclosure is to provide a display apparatus capable of preventing leakage of light generated from a plurality of sub-pixels.

The objects to be accomplished according to an embodiment of the present disclosure are not limited to the ones described above, and other objects and advantages of the present invention which are not mentioned can be understood from the following description, and will be more clearly understood from the embodiments of the present invention. Furthermore, it will be readily appreciated that the objects and advantages of the present disclosure can be realized by the means presented in the claims, and combinations thereof.

A display apparatus according to an embodiment of the present disclosure may include a first substrate including a plurality of sub-pixels, a plurality of light-emitting elements disposed respectively in the sub-pixel, and a reflective structure disposed between adjacent light-emitting elements, and each of the plurality of light-emitting elements may include a spherical structure.

According to an embodiment of the present disclosure, it is possible to provide a display apparatus with an improved brightness realized by increasing a light-emitting surface area by emitting light through a sphere-shaped first electrode in each of a plurality of sub-pixels in all directions of the surface of the sphere.

Additionally, according to an embodiment of the present disclosure, the light collection efficiency can be improved by preventing the mixing of light and the light leakage phenomenon in the downward direction of the sphere-shaped first electrode with the use of the reflective structure disposed between adjacent sub-pixels.

Additionally, according to an embodiment of the present disclosure, the sub-pixels can be distinguished from each other by the respective first electrodes. Thereby, banks for distinguishing sub-pixels from each other can be omitted, thus preventing a reduction in aperture ratio. As a result, the aperture ratio of each sub-pixel can be improved.

Therefore, according to an embodiment of the present disclosure, it is possible to provide a display apparatus capable of realizing high color reproducibility and high brightness, thereby enabling the operation at low power and the reduction in power consumption.

The present disclosure may have other effects besides the aforementioned ones, which are clearly recognizable to a person skilled in the art from the description below.

It is to be understood that both the foregoing general description and the following detailed description are exemplary and explanatory and are intended to provide further explanation of the inventive concepts as claimed.

### BRIEF DESCRIPTION OF THE DRAWINGS

FIG. 1 is a plan view of a display apparatus according to an embodiment of the present disclosure;

FIG. 2 is a plan view showing pixels in which a plurality of sub-pixels according to an embodiment of the present disclosure are disposed;

FIG. 3 is a cross-sectional view taken along line I-I' in FIG. 2 in an embodiment of the present disclosure;

FIG. 4 is a perspective view of a unit pixel according to an embodiment of the present disclosure;

FIGS. 5 to 17 are views showing a method for manufacturing a display apparatus according to an embodiment of the present disclosure; and

FIGS. 18 and 19 are plan views showing pixels according to other embodiments of the present disclosure.

### DETAILED DESCRIPTION

Advantages and features of the present disclosure, and a method of achieving the advantages and features will become apparent when referring to the following embodiments described later in detail together with the accompanying drawings. However, the present disclosure is not limited to the embodiments as disclosed below, but may be embodied in various different forms. Thus, these embodiments are set forth only to make the present disclosure complete, and to completely inform the scope of the present disclosure to those of ordinary skill in the technical field to which the present disclosure belongs.

A shape, a size, a ratio, an angle, a number, etc. disclosed in the drawings for illustrating embodiments of the present disclosure are illustrative, and the present disclosure is not limited thereto. Throughout the detailed description, like reference symbols refer to like components. Further, in describing the present disclosure, if it is determined that a detailed description of a related known technology may unnecessarily obscure the gist of the present disclosure, the detailed description thereof will be omitted. When the terms "comprise", "include", "have", "be configured with", "be comprised of", and the like are used in the present disclosure, the presence or addition of other element may be allowable, unless the term “only” is used. When using an expression in a singular form to describe a component, it can include a meaning of a plural form unless explicitly stated to the contrary.

It should be noted that any component will be construed as including a tolerance or error range, even if there is no explicit description thereof.

In describing a position relationship between two elements, for example, when the position relationship is described using “on”, “above”, “below”, “next to”, and the like, one or more other elements may be interposed between the two elements unless “just”, “directly”, or "close" is used.

In describing a temporal relationship, for example, when the temporal order is described as “after”, “subsequent”, “next”, “before”, and the like, the case which is not continuous may also be included unless the term “just” or “directly” is used.

It will be understood that, although the terms “first”, “second”, etc. may be used herein to describe various elements, these elements should not be limited by these terms. These terms are merely used to distinguish one element from another element. So, a first element referred to in the following description may represent a second element, without departing from the scope of the technical idea of the present disclosure.

The individual features of the various embodiments of the present disclosure may be coupled or combined with each other in part or in whole to be interconnected and operated in a variety of technical ways, and each embodiment may be implemented independently of each other or implemented together in an associative relationship.

Hereinafter, a display apparatus according to each embodiment of this disclosure will be described with reference to the accompanying drawings.

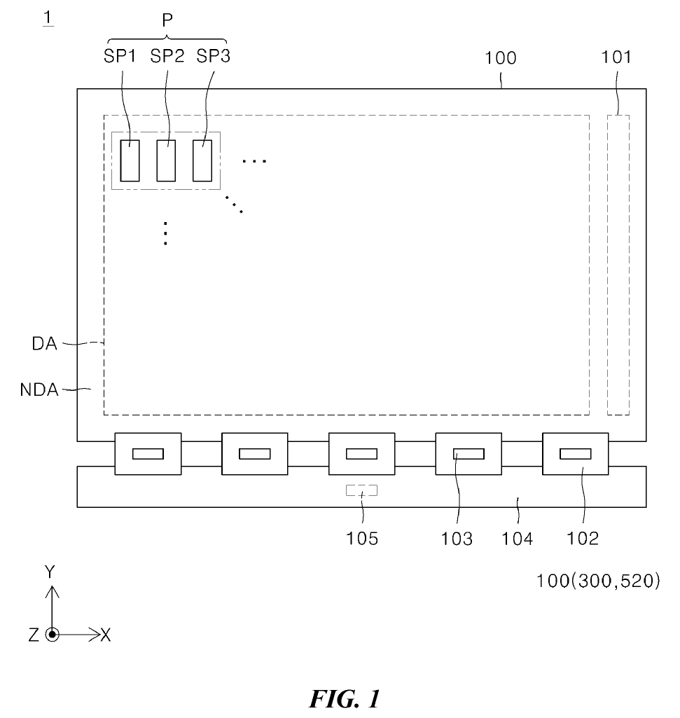

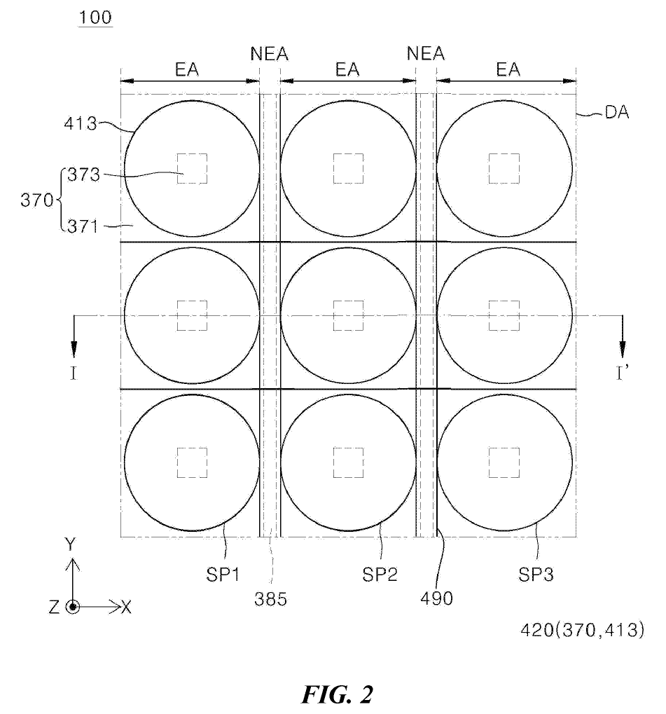

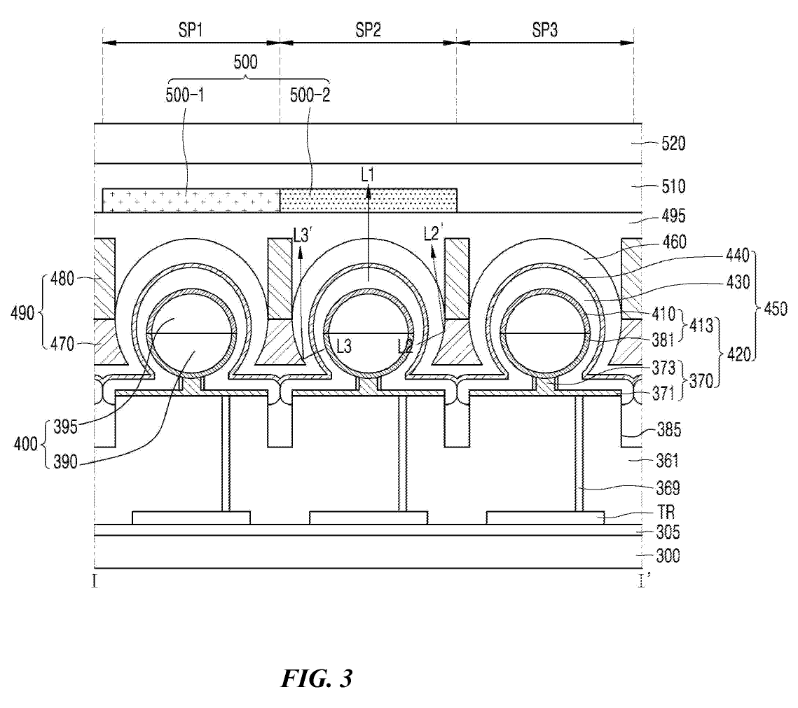

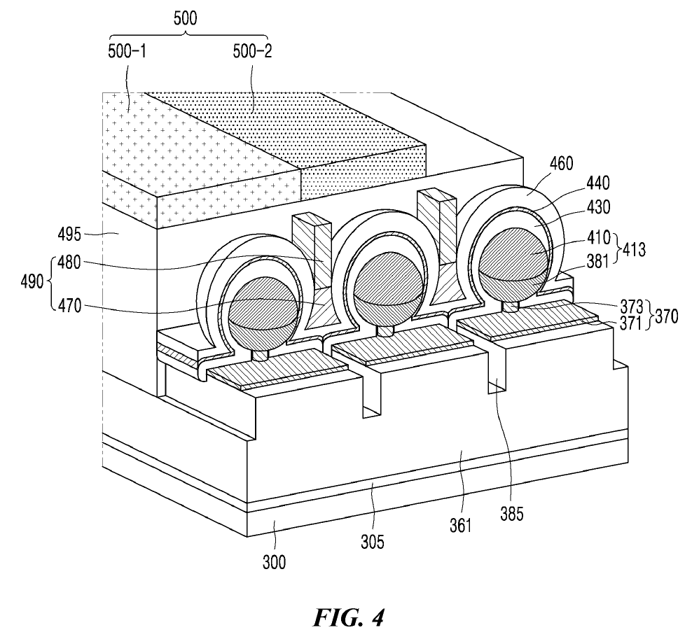

FIG. 1 is a plan view of a display apparatus according to an embodiment of the present disclosure. FIG. 2 is a plan view showing pixels in which a plurality of sub-pixels according to an embodiment of the present disclosure are disposed. FIG. 3 is a cross-sectional view taken along line I-I' in FIG. 2 in an embodiment of the present disclosure. And FIG. 4 is a perspective view of a unit pixel according to an embodiment of the present disclosure. For convenience of explanation, FIG. 2 illustrates the first electrode 420, trench 385, and reflective structure 490, but other components may be included in the display apparatus.

Referring to FIGS. 1 to 4, a display apparatus 1 according to an embodiment of the present disclosure may include a display panel 100 having a display area DA and a non-display area NDA located outside the display area DA. The display panel 100 according to an embodiment of the present disclosure may include a first substrate 300 and a second substrate 520. The first substrate 300 may include a plurality of light-emitting elements and circuit elements for driving the light-emitting elements and the second substrate 520 may be a cover substrate. This will be described later in further detail.

The display area DA may be an area where an image is displayed. The non-display area NDA may be an area where no image is displayed. The non-display area NDA may be located in the peripheral area (or border area) of the display panel 100; however, this is not exhaustive. For example, the remaining portion of the display area DA except an emission area from which light is emitted to the outside may be referred to as the non-display area NDA. As an example, the non-display area NDA may fully or partially surround the display area DA, without being limited thereto. As an example, the non-display area NDA may be at least partially invisible from the front side of the display panel 100, for example, by being bent toward the rear side of the display panel 100, without being limited thereto. As an example, the entire non-display area NDA may be flat, without being bent.

In the display area DA, a plurality of pixels P may be disposed. Through the plurality of pixels P in the display area DA, an image can be displayed. In the non-display area NDA, there may be disposed various wirings and circuits for driving the plurality of pixels P in the display area DA. For example, in the non-display area NDA, there may be disposed driving circuits including a gate driving circuit and a data driving circuit. In the non-display area NDA, there may be disposed several drivers 101 for driving the display area AA. For example, the driver 101 may include, but is not limited to, a gate driver and a data driver. Embodiments are not limited thereto. As an example, at least one or each of the drivers 101 may be not disposed in the non-display area NDA. As an example, at least one or each of the drivers 101 may be provide on a separate panel or film, and connected to the display panel 100 using a tape automated bonding (TAB) method, a chip-on-glass (COG), a chip-on-panel (COP) method, or a chip-on-film (COF) method, without being limited thereto.

As an example, in at least one side edge of the non-display area NDA a flexible circuit board 102 and a printed circuit board 104 may be disposed, without being limited thereto. For example, a plurality of flexible circuit boards 102 may be disposed; however, this is not exhaustive. On the flexible circuit board 102 an integrated circuit chip 103 may be disposed. The flexible circuit board 102 may be coupled with the display panel 100 at one side, and with the printed circuit board 104 at the other side, so that powers and signals for driving light-emitting elements supplied from the printed circuit board 104 can be provided to the display area DA of the display panel 100. For example, a signal for driving a light-emitting element may include a high-potential voltage, a low-potential voltage, a scan signal, a data signal, or the like, without being limited thereto.

The printed circuit board 104 may supply signals to the integrated circuit chip 103 disposed on the flexible circuit board 102. On the printed circuit board 104, there may be disposed various components for supplying various signals to the integrated circuit chip 102. For example, on the printed circuit board 104, there may be included a timing controller 105, without being limited thereto.

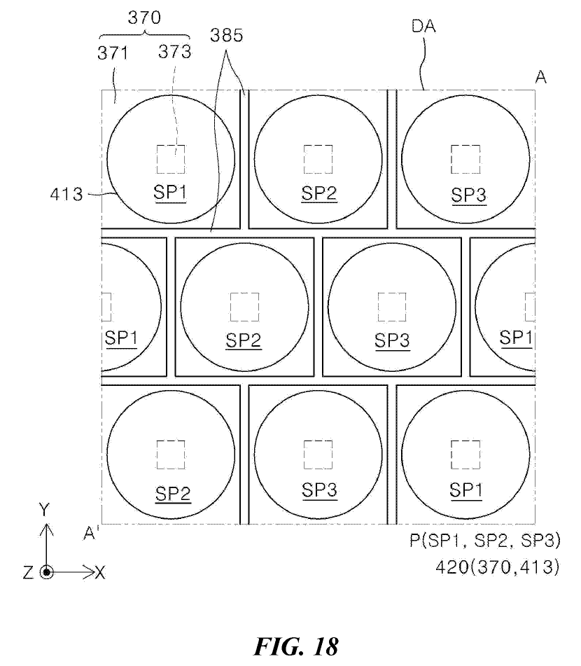

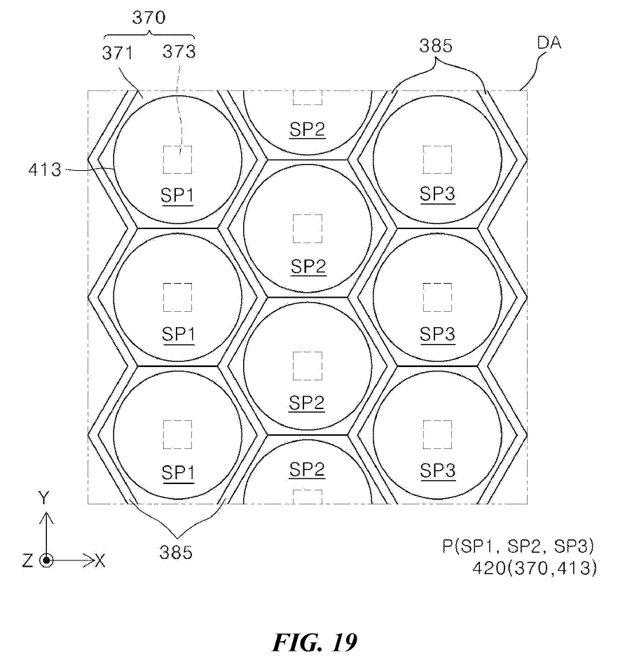

Each of the plurality of pixels P of the display area DA may be constituted with a plurality of sub-pixels SP1, SP2, SP3. The plurality of sub-pixels SP1, SP2, SP3 may be disposed in an array on the display area DA. In an example, a plurality of sub-pixels SP1, SP2, SP3 may be spaced apart from each other in a first direction of the display area AA and a second direction intersecting the first direction to be disposed in a matrix type array. The first direction may be a horizontal direction, an X-axis direction, or a row direction, while the second direction may be a vertical direction, a Y-axis direction, or a column direction. However, this is not exhaustive, and the number of sub-pixels constituting each pixel, the arrangement shape, arrangement order, and arrangement direction of the sub-pixels SP1, SP2, SP3 may be changed in various ways. For example, the sub-pixels SP1, SP2, SP3 may be arranged in a honeycomb shape, or to be staggered with respect to each other. This will be described later in further detail with reference to FIGS. 18 and 19.

Referring to FIGS. 2 to 4, the plurality of sub-pixels SP1, SP2, SP3 may be disposed in the display area DA of the display panel 100. In an example, sub-pixels SP1 emitting light of the same color may be arranged in the second direction, which is the column direction of the display panel 100. Sub-pixels SP1, SP2, SP3 emitting lights of different colors may be arranged to be spaced apart from each other in the first direction, which is the row direction of the display panel 100. Embodiments are not limited thereto. As an example, sub-pixels SP1 emitting light of the same color may be arranged in the first direction, while sub-pixels SP1, SP2, SP3 emitting lights of different colors may be arranged to be spaced apart from each other in the second direction. As an example, the first direction and the second direction may be directions other than the column direction and the row direction. As an example, sub-pixels SP1 emitting light of the same color may be not arranged in the same line, or sub-pixels SP1, SP2, SP3 emitting lights of different colors may be not arranged in the same line, without being limited thereto.

A plurality of emission areas EA may be positioned corresponding to the sub-pixels SP1, SP2, SP3, respectively. On each of the plurality of sub-pixels SP1, SP2, SP3 the first electrode 420 may be disposed. The plurality of sub-pixels SP1, SP2, SP3 may be distinguished from each other by the first-first electrodes 370 of their own first electrodes 420. For example, the first portion 371 of the first-first electrode 370 may have a flat plate shape when viewed in a plan view. Since the first portions 371 of the first-first electrodes 370 of the sub-pixels are arranged spaced apart from each other, adjacent sub-pixels can be distinguished from each other. Accordingly, the bank for distinguishing each sub-pixel can be omitted.

The light-emitting areas EA of the sub-pixels SP1, SP2, SP3 may be distinguished from each other by a plurality of reflective structures 490. The area in which the plurality of reflective structures 490 are disposed may be the non-emission area NEA. That is, the area in which the first electrode 420 is disposed, and which is exposed without being covered by the reflective structure 490 may be the emission area EA. The plurality of reflective structures 490 may include a reflective material.

Referring to FIGS. 3 and 4, the display panel 100 may include the first substrate 300, a plurality of transistors TR on the first substrate 300, the plurality of light-emitting elements 450 respectively electrically connected to the plurality of transistors TR through contact structures 369, the reflective structure 490 disposed between adjacent light-emitting elements 450, a planarization layer 495 disposed on the reflective structure 490, a color conversion layer 500 on the planarization layer 495, a protective layer 510, and the second substrate 520. In FIG. 4, the transistor TR and contact structure 369 have been omitted from the illustration. Embodiments are not limited thereto. As an example, at least one of the above-mentioned components may be omitted, or at least one additional component may be further included.

The plurality of transistors TR may be disposed on the first substrate 300. The plurality of transistors TR may include switching transistors and driving transistors, without being limited thereto. Between the first substrate 300 and the transistor TR a buffer layer 305 may be disposed, without being limited thereto.

The transistor TR may include a semiconductor layer, a gate electrode, and source/drain electrodes. The transistor TR may be covered with an insulating structure 361. The insulating structure 361 may be configured as a single layer structure or a multilayer structure in which a plurality of insulating layers are stacked in an up and down direction.

The first electrode 420 may be disposed on the insulating structure 361. The first electrode 420 may include the first-first electrode 370, a first-second electrode 381, and a first-third electrode 410. The transistor TR may be electrically connected to the first electrode 420 via the contact structure 369 penetrating through the insulating structure 361.

The first-first electrode 370 may include the first portion 371 and a second portion 373. The first portion 371 may have a flat plate shape when viewed in a plan view. The first portion 371 may have a regular polygonal shape whose respective sides have the same length and whose respective angles are all the same. For example, the first portion 371 may have a square shape; however, this is not exhaustive. As an example, the first portion 371 may have a circular shape, an oval shape or a polygonal shape whose respective sides have different lengths or whose respective angles are different, without being limited thereto. The second portion 373 may have a pillar shape that protrudes from the upper surface of the first portion 371 and has a predetermined height. The second portion 373 may be formed in one body with the first portion 371, or may be separately formed with the first portion 371, without being limited thereto. As an example, the second portion 373 and the first portion 371 may include the same material or different materials, in the same process or separate processes. The first-first electrode 370 may include a conductive material. For example, the first-first electrode 370 may include a transparent metal oxide, without being limited thereto.

The first-first electrode 370 may distinguish adjacent sub-pixels from each other. On the second portion 373 of the first-first electrode 370 the first-second electrode 381 may be disposed. The first-second electrode 381 may have a hemispherical shape concave toward the first-first electrode 370, without being limited thereto. The first-third electrode 410 may be disposed on the upper side of the first-second electrode 381. The first-third electrode 410 may have a hemispherical shape convex opposite to the first-first electrode 370 and toward the second substrate 520, without being limited thereto. Accordingly, the first-second electrode 381 and the first-third electrode 410 can be implemented as a sphere-shaped structure 413 in which a convex hemisphere is combined on the upper side of a concave hemisphere, without being limited thereto. As an example, an end portion of the first-second electrode 381 may be in contact with an end portion of the first-third electrode 410. As an example, a diameter of the first-second electrode 381 may have the same size as the diameter of the first-third electrode 410. As an example, the first-second electrode 381 and the first-third electrode 410 may seal the space therebetween, without being limited thereto.. The first-second electrode 381 and the first-third electrode 410 may be configured with a conductive material. For example, the first-second electrode 381 and the first-third electrode 410 may include a transparent metal oxide. The first-first electrode 370, the first-second electrode 381, and the first-third electrode 410 may include and be configured with the same material. However, this is not exhaustive. The first space inside the first-second electrode 381 and the second space inside the first-third electrode 410 may be filled with a mold structure 400 (see FIG. 3). The mold structure 400 may configure the exterior shape of the sphere-shaped structure 413. The mold structure 400 may include an insulating material, without being limited thereto. For example, the mold structure 400 may include an organic insulating material.

Between adjacent sub-pixels the trench 385 may be disposed. For example, the trench 385 may be disposed between the first sub-pixel SP1 and the second sub-pixel SP2. For example, the trench 385 may be disposed between the second sub-pixel SP2 and the third sub-pixel SP3. The trench 385 may be formed in the thickness direction of the insulating structure 361. As an example, the trench 385 may be formed in the thickness direction of the insulating structure 361 from an upper surface of the insulating structure 361. In one example, the trench 385 may distinguish adjacent sub-pixels from each other together with the first-first electrode 370 of the first electrode 420. Accordingly, the bank for distinguishing sub-pixels from each other can be omitted. In an example, the bank may be formed to partially cover the edge of the first electrode 420. In this case, the aperture ratio may decrease by the portion covered with the bank, thereby reducing the emission area. Therefore, according to an embodiment of the present disclosure, the bank can be omitted, thereby reducing or preventing a reduction in the aperture ratio of the emission area. As a result, the portion of the first electrode 420 which otherwise would be covered by the bank can also be secured as the emission area, so that the aperture ratio of the display apparatus can be improved.

A light-emitting layer 430 may be disposed on the first electrode 420. The light-emitting layer 430 may be configured with an organic material, without being limited thereto. For example, the light-emitting layer 430 may include an organic material that emits blue light. The light-emitting layer 430 may be disposed on the entire surface of the display area DA while covering the first electrode 420 including the sphere-shaped structure 413. The light-emitting layer 430 may be disposed continuously without any disconnection on the sub-pixels SP1, SP2, SP3. To this end, the second portion 373 of the first-first electrode 370 of the first electrode 420 may be configured to have a thickness smaller than the thickness of the light-emitting layer 430. The light-emitting layer 430 may be formed to conform to the shape of the sphere-shaped structure 413, thus having a sphere shape.

A second electrode 440 may be disposed on the light-emitting layer 430. The second electrode 440 may be a cathode electrode. The second electrode 440 may be formed across the entire surface of the first substrate 300. Since the light-emitting layer 430 is formed continuously without any disconnection under the second electrode 440, the second electrode 440 can also be formed to have a continuous shape. The second electrode 440 may include a conductive material. For example, the second electrode 440 may include a transparent metal oxide, without being limited thereto. The second electrode 440 may be disposed to conform to the shape of the first electrode 420 and the light-emitting layer 430, thus having a convexly protruding sphere shape. The light-emitting element 450 may include and be configured with the first electrode 420, the light-emitting layer 430, and the second electrode 440.

The light-emitting element 450 may include a sphere-shaped structure. Accordingly, the light-emitting element 450 can emit light in all directions from the surface of the sphere-shaped structure. For example, light can be emitted from the sphere-shaped structure in an upward direction, a lateral direction, and a downward direction. That is, the brightness of the display apparatus can be improved with the increase in the light-emitting surface area obtained by allowing light to be emitted in all directions from the surface of the sphere.

An encapsulation layer 460 may be disposed on the light-emitting element 450. The encapsulation layer 460 may be disposed to conform to the shape of the second electrode 440 of the light-emitting element 450. Thereby, the encapsulation layer 460 may have a convexly protruding shape. The encapsulation layer 460 may include a spacing space disposed between adjacent sub-pixels. The reflective structure 490 may be disposed in the spacing space. As an example, the encapsulation layer 460 may be formed across the entire surface of the first substrate 300. As an example, the encapsulation layer 460 may be formed to have a continuous shape even between adjacent sub-pixels. As an example, the encapsulation layer 460 may include a spacing space disposed between adjacent sub-pixels above the encapsulation layer 460 formed between adjacent sub-pixels.

The reflective structure 490 may include a first reflective pattern 470 and a second reflective pattern 480, without being limited thereto. The first reflective pattern 470 may include a bottom surface, an upper surface, and an inclined surface extending from the bottom surface to the upper surface. The width of the first reflective pattern 470 may become narrower as it goes toward the second substrate 520. Thereby, the inclined surface of the first reflective pattern 470 may have a slope at which it is inclined forming a predetermined angle with respect to the bottom surface. For example, the inclined angle of the slope may be an acute angle less than 90 degrees. The second reflective pattern 480 may be disposed so that its bottom surface is in contact with the upper surface of the first reflective pattern 470. The second reflective pattern 480 may have the bottom and upper surfaces of the same width. Thereby, the bottom surface and side surface of the second reflective pattern 480 may be configured to have a 90-degree angle therebetween. Embodiments are not limited thereto. As an example, the bottom surface of the second reflective pattern 480 may have the same area as the upper surface of the first reflective pattern 470, without being limited thereto. As an example, the bottom and upper surfaces of the second reflective pattern 480 may also have different widths. As an example, the upper surface of the second reflective pattern 480 may have a greater width or a smaller width than the bottom surface of the second reflective pattern 480.

The first reflective pattern 470 and the second reflective pattern 480 may include a material (e.g., a metal material) having a high reflectivity. For example, the first reflective pattern 470 and the second reflective pattern 480 may include a metal material having the same reflectivity. As an example, the first reflective pattern 470 and the second reflective pattern 480 may include the same material or different materials. As an example, the first reflective pattern 470 and the second reflective pattern 480 may be formed in one body, or may be separately formed.

The reflective structure 490 can increase the amount of light generated from the light-emitting element 450 and emitted to the outside through the second substrate 520, thereby improving light extraction efficiency. The reflective structure 490 can prevent light generated from the light-emitting element 450 from leaking toward the first substrate 300 and improve the efficiency of focusing light toward the second substrate 520.

The light-emitting element 450 includes the first electrode 420 including the sphere-shaped structure 413, so that light can be emitted in various directions. For example, as shown in FIG. 3, lights L1, L2, L3 may be generated in an upward direction, a lateral direction, and a downward direction of the light-emitting element 450. The first light L1 generated in the upward direction from the light-emitting element 450 may pass through the color conversion layer 500 and be emitted to the outside. The light L2 generated in the lateral direction from the light-emitting element 450 may be reflected by the reflective structure 490 to be changed into a second light L2' whose advancing path is changed toward the color conversion layer 500. In addition, the light L3 generated in the downward direction of the sphere-shaped structure 413 from the light-emitting element 450 may be reflected by the first reflective pattern 470 disposed at the lower side of the reflective structure 490 and having the inclined surface, thereby being changed into a third light L3'.

Accordingly, it is possible to improve the light extraction efficiency by preventing the downward leakage of light generated from the light-emitting element 450, and thus the resulting loss of light, and by changing the advancing path of light toward the color conversion layer 500.

Further, as an example, the first reflective pattern 470 may be in contact with the outer surface of the encapsulation layer 460, and the second reflective pattern 480 may be disposed to be spaced apart from the outer surface of the encapsulation layer 460, without being limited thereto. If the second reflective pattern 480 is configured to fill the entire spacing space of the encapsulation layer 460, the light generated from the light-emitting element 450 would change its path by being reflected by the second reflective pattern 480 toward the first substrate 300 instead of the color conversion layer 500, or back toward the light-emitting element 450, thus resulting in light loss. For this reason, the second reflective pattern 480 may be disposed to be spaced apart from the outer surface of the encapsulation layer 460. As an example, the first reflective pattern 470 may be configured to fill the spacing space of the encapsulation layer 460. As an example, the first reflective pattern 470 be in contact with the upper surface of the encapsulation layer 460 formed between adjacent subpixels, and with a lower side surface of the encapsulation layer 460, without being limited thereto. As an example, the boundary between the first reflective pattern 470 and the second reflective pattern 480 may be lower than, common to or higher than the boundary between the first-second electrode 381 and the first-third electrode 410, without being limited thereto.

Referring to FIGS. 2 to 4 together, the reflective structure 490 may be disposed to overlap with the trench 385 in an up and down direction. For example, as shown in FIG. 2, in the case where the trench 385 is configured in a line shape along the second direction in the display area DA, the reflective structure 490 may be disposed in a line shape to overlap with the trench 385 in the up and down direction thereof.

On the reflective structure 490 and the encapsulation layer 460, the planarization layer 495 may be disposed. The planarization layer 495 may include and be configured with an organic insulating material to implement a flat surface.

On the planarization layer 495 the plurality of color conversion layers 500 may be disposed. In an example, the color conversion layer 500 may overlap with one or more of the plurality of sub-pixels. The color conversion layer 500 may include a first color conversion layer 500-1 disposed in the first sub-pixel SP1, and a second color conversion layer 500-2 disposed in a second sub-pixel SP2. The third sub-pixel SP3 may emit a blue light generated from the light-emitting element 450 without the color conversion layer 500 to the outside through the second substrate 520. Embodiments are not limited thereto. As an example, the color conversion layer 500 may also be disposed in the third sub-pixel SP3.

The light-emitting layer 430 of the light-emitting element 450 according to an embodiment of the present disclosure may be an organic material that emits blue light. The light-emitting element 450 according to an embodiment of the present disclosure can emit light in various directions because it includes the first electrode 420 including the sphere-shaped structure 413. For example, light can be emitted in an upward direction, a lateral direction, and a downward direction of the light-emitting element 450. In the case where the light-emitting layer 430 of the light-emitting element 450 generates white light, a color filter may be applied to convert the color of the light emitted to the outside. In this case, as the angle of emission of the white light becomes higher than the horizontal direction, the color of the light emitted to the outside through the color filter may become more different color from the target color, which may result in a decrease in color reproducibility.

For this reason, in order to improve the color reproducibility, the light-emitting element 450 according to an embodiment of the present disclosure may allow each sub-pixel SP1, SP2, SP3 to emit blue light of the same color, and control the color emitted to the outside via the color conversion layer 500.

The protective layer 510 may be disposed on the color conversion layer 500. The protective layer 510 can protect the color conversion layer 500 and make level the steps generated by the color conversion layer 500. On the protective layer 510 the second substrate 520 may be disposed. The second substrate 520 may include a transparent material. As an example, the second substrate 520 may include glass or a plastic film, without being limited thereto. The second substrate 520 may also be referred to as a cover window, window cover, or cover glass which covers the first substrate 300.

The display apparatus according to an embodiment of the present disclosure can increase the brightness of light emitted from the display panel by configuring the first electrode of the light-emitting element to include the sphere structure, thereby increasing the light-emitting surface area. Additionally, it can improve the color reproducibility by allowing each sub-pixel in which the light-emitting element including the sphere-shaped structure is disposed to emit blue light and controlling the color emitted from the each sub-pixel via the color conversion layer.

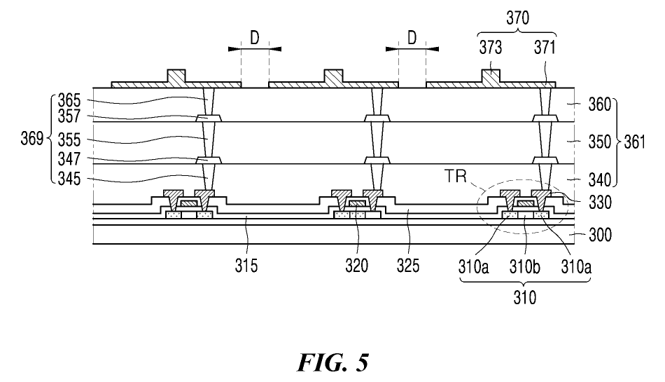

FIGS. 5 to 17 are views showing a method for manufacturing a display apparatus according to an embodiment of the present disclosure. In FIGS. 5 to 17, the same reference symbols as those in FIGS. 2 to 4 may represent the same components.

Referring to FIG. 5, the plurality of transistors TR may be disposed on the first substrate 300. The first substrate 300 may include a silicon wafer, without being limited thereto. In an example, the first substrate 300 may include glass or a plastic film, without being limited thereto.

On the first substrate 300 a buffer layer 305 may be disposed. The buffer layer 305 can prevent moisture or impurities from penetrating from the first substrate 300 toward the transistor TR. The buffer layer 305 may be disposed in a single-layer or multilayer structure formed of an inorganic insulating material such as silicon oxide (SiOx), silicon nitride (SiNx) or the like.

The transistor TR may be disposed on the buffer layer 305. Examples of the transistor TR may include a switching transistor and a driving transistor. For example, the switching transistor and the driving transistor may be formed on the first substrate 300 with the use of a complementary metal oxide semiconductor (CMOS) process.

The switching transistor is switched according to the gate signal supplied to the gate wiring to supply the data voltage supplied from the data wiring to the driving transistor, and select the sub-pixel SP1, SP2, SP3. The driving transistor supplies power from the switching transistor to the first electrode of the selected sub-pixel SP1, SP2, SP3 to drive the light-emitting element.

On the buffer layer 305 a semiconductor layer 310 may be disposed. The semiconductor layer 310 may be comprised of an oxide semiconductor or a silicon-based semiconductor material. For example, the semiconductor layer 310 may include a transparent oxide semiconductor material such as indium-gallium-zinc-oxide (IGZO) or indium-zinc-oxide (IZO). Alternatively, the semiconductor layer 310 may include a polysilicon semiconductor material.

The semiconductor layer 310 may include a source/drain region 310a and a channel region 310b. A gate electrode 320 may be disposed to be spaced apart from the semiconductor layer 310. Between the gate electrode 320 and the semiconductor layer 310 a gate insulating layer 315 may be disposed. The gate insulating layer 315 may be configured in a single layer or multiple layers of silicon oxide (SiOx) or silicon nitride (SiNx), without being limited thereto. The region of the semiconductor layer 310 that overlaps with the gate electrode 320 in the up and down direction may be the channel region 310b. The source/drain regions 310a may be disposed on the opposite sides of the channel region 310b, respectively, without being limited thereto.

On the gate electrode 320 a passivation layer 325 may be disposed. Source/drain electrodes 330 may be disposed with the gate electrode 320 interposed therebetween to penetrate through the passivation layer 325 and the gate insulating layer 315. The source/drain electrodes 330 may be connected to the source/drain regions 310a of the semiconductor layer 310, respectively. The source/drain electrodes 330 may extend partially to the upper surface of the passivation layer 325. The transistor TR may include and be configured with the semiconductor layer 310, the gate insulating layer 315, the gate electrode 320, and the source/drain electrodes 330.

The insulating structure 361 may be disposed. The insulating structure 361 may include a first insulating layer 340, a second insulating layer 350, and a third insulating layer 360 which are stacked from the lower side in an upward down direction, without being limited thereto. The first insulating layer 340 of the insulating structure 361 may be disposed on the passivation layer 325 and the source/drain electrodes 330. The first insulating layer 340 may include an inorganic insulating material or an organic insulating material. The first insulating layer 340 may cover the transistors TR, various signal wirings, capacitors, and the like, all of which are disposed on the first substrate 300.

A plurality of first connection patterns 347 may be disposed to be spaced apart from each other on the first insulating layer 340. A plurality of first via electrodes 345 may be disposed to penetrate through the first insulating layer 340. Each first via electrode 345 may be connected to each first connection pattern 347 at one surface, and be electrically connected to the transistor TR at the other surface. For example, a plurality of first connection patterns 347 may be connected to one of the source/drain electrodes 330 of the transistor TR.

The second insulating layer 350 may be disposed on the first insulating layer 340 and the first connection pattern 347. The second insulating layer 350 may include an organic insulating material. On the second insulating layer 350 a plurality of second connection patterns 347 may be disposed to be spaced apart from each other. A plurality of second via electrodes 355 may be disposed to penetrate through the second insulating layer 350. Each second via electrode 355 may be connected to each second connection pattern 357 at one surface, and be connected to the first connection pattern 347 at the other surface.

The third insulating layer 360 may be disposed on the second insulating layer 350 and the second connection pattern 357. The third insulating layer 360 may include an organic insulating material. A plurality of third via electrodes 365 may be disposed to penetrate through the third insulating layer 360.

The plurality of first-first electrodes 370 may be disposed to be spaced apart from each other on the third insulating layer 360. For example, adjacent first-first electrodes 370 may be disposed to be spaced apart from each other with a predetermined space D interposed therebetween. As an example, at a location corresponding to the space D between adjacent first-first electrodes 370, a trench may be formed later so that adjacent sub-pixels can be distinguished from each other.

The first-first electrode 370 may include the first portion 371 and the second portion 373 protruding from the first portion 371. Referring to FIG. 2 together, the first portion 371 of the first-first electrode 370 may have a flat plate shape when viewed in a plan view. The second portion 373 may have a pillar shape protruding from the upper surface of the first portion 371. The second portion 373 may be disposed in the central portion of the first portion 371, or may be biased from the central portion of the first portion 371. The second portion 373 may have a square shape when viewed in a plan view; however, this is not exhaustive. For example, the second portion 373 may have a circular shape, an oval shape, a polygonal shape, etc.

The first-first electrode 370 may include a first metal oxide. The first metal oxide may be a transparent metal oxide. For example, the first metal oxide may include indium tin oxide (ITO) or indium zinc oxide (IZO). The first portion 371 of the first-first electrode 370 may be connected to the third via electrode 365.

The first via electrode 345, the first connection pattern 347, the second via electrode 355, the second connection pattern 357, and the third via electrode 365 may be disposed to overlap with each other in an up and down direction. Thereby, the circuit element such as the transistor TR or the like disposed in the lower side may be electrically connected to the first-first electrode 370. The first via electrode 345, the first connection pattern 347, the second via electrode 355, the second connection pattern 357, and the third via electrode 365 may be the contact structure 369 that electrically connects the first-first electrode 370 with the circuit element disposed in the lower side.

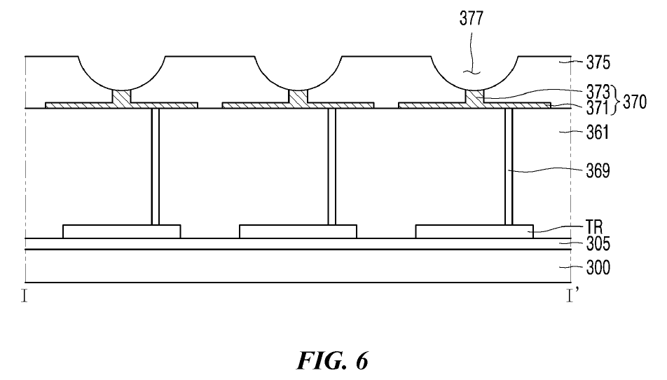

Referring to FIG. 6, on the first-first electrode 370 a frame layer 375 may be disposed. For convenience of explanation, in FIG. 6, the transistor TR, the insulating structure 361, and the contact structure 369 are simply illustrated.

The frame layer 375 may include an insulating material (e.g., an organic insulating material). For example, the frame layer 375 may include, but is not limited to, an epoxy-based resin.

The frame layer 375 may include a concave portion 377. The concave portion 377 formed on the frame layer 375 may be formed using, for example, a halftone mask, a slit mask, or the like, without being limited thereto. The concave portion 377 may expose the upper surface of the second portion 373 of the first-first electrode 370. It may have a shape concave toward the first portion 371 of the first-first electrode 370. The frame layer 375 may become thinner as it goes toward the second portion 373 of the first-first electrode 370. For example, the concave portion 377 may have a hemisphere shape, without being limited thereto. The concave portion 377 may have a semicircular shape when viewed in cross-section, without being limited thereto. The upper surface of the second portion 373 of the first-first electrode 370 may have a gentle shape to conform to the semicircular shape of the concave portion 377.

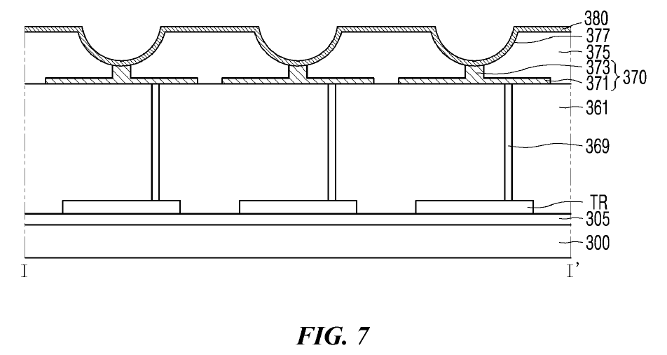

Referring to FIG. 7, a first-second electrode material layer 380 is formed on the frame layer 375. The first-second electrode material layer 380 may be formed in a concave shape conforming to the shape of the concave portion 377.

The first-second electrode material layer 380 may include a second metal oxide, without being limited thereto. The second metal oxide may be a different material from the first metal oxide. For example, the second metal oxide may include a material having a relatively faster etching rate than that of the first metal oxide. As an example, the second metal oxide may include a relatively higher content of oxygen respectively in indium tin oxide (ITO) or indium zinc oxide (IZO) than the first metal oxide, without being limited thereto. Embodiments are not limited thereto. As an example, the second metal oxide may be the same as the first metal oxide. As an example, the second metal oxide may include a material having the same etching rate as that of the first metal oxide. As an example, the first-second electrode material layer 380 may include a conductive material other than the metal oxide.

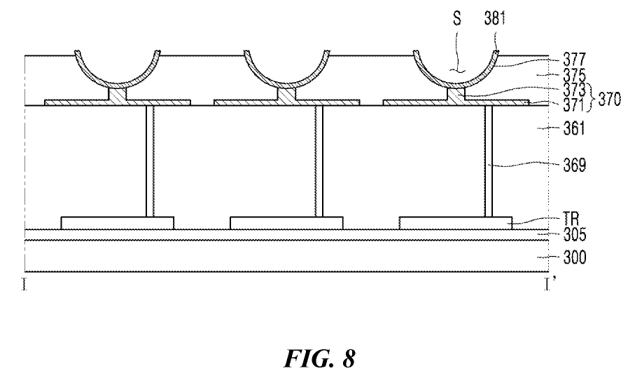

Referring to FIG. 8, the first-second electrode material layer 380 is patterned to form the first-second electrode 381. For example, the first-second electrode 381 may be formed by removing the first-second electrode material layer 380 disposed on the frame layer 375 between adjacent first-first electrodes 370. The first-second electrode 381 may be connected to the exposed surface of the second portion 373 of the first-first electrode 370. The first-second electrode 381 may have a concave shape as it is formed to conform to the shape of the concave portion 377 of the frame layer 375. For example, the first-second electrode 381 may have a concave hemispherical shape. Thereby, the first-second electrode 381 may have a concave hemispherical space S disposed in the inside thereof.

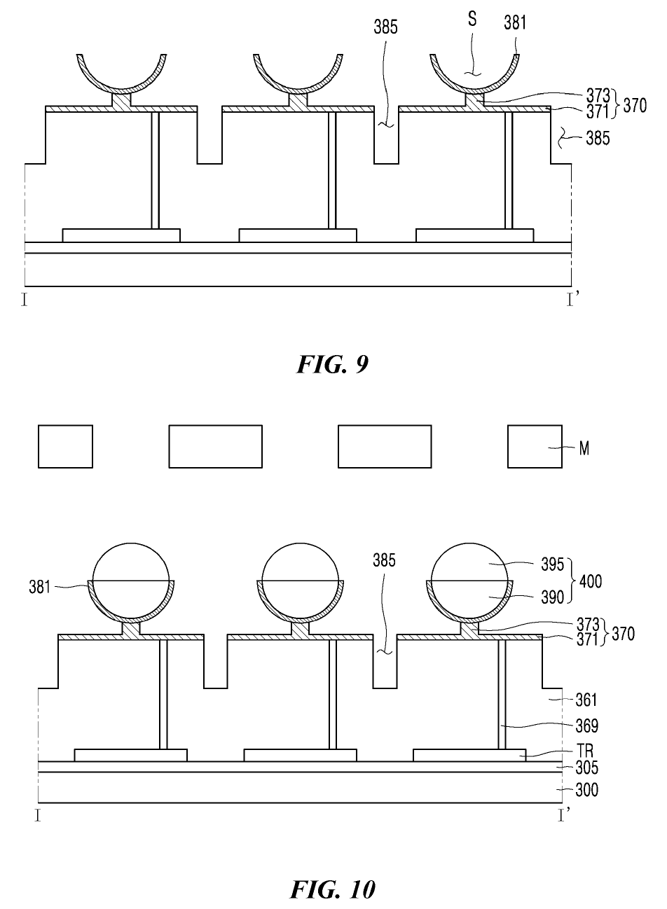

Referring to FIG. 9, the frame layer 375 is removed, and a plurality of trenches 385 are formed. For this purpose, the frame layer 375 may be removed through an ashing process using plasma. For example, the plasma may utilize oxygen plasma. However, this is not exhaustive. Then, the upper surface of the insulating structure 361 between the adjacent first-first electrodes 370 may be exposed.

In a subsequent step, the insulating structure 361 may be etched in the thickness direction toward the first substrate 300 to form the trench 385. The trench 385 may include a bottom surface and two side surfaces extending from the bottom surface. Referring to FIG. 2 together, the trench 385 may be disposed in a boundary area between two adjacent sub-pixels. For example, the trench 385 may be disposed in a boundary area between the first sub-pixel SP1 and the second sub-pixel SP2. For example, the trench 385 may be disposed in a boundary area between the second sub-pixel SP2 and the third sub-pixel SP3. The trench 385 may be disposed in a non-emitting area NEA between emission areas EA. In an example, the trench 385 may be disposed to extend along the Y-axis direction, which is the column direction; however, this is not exhaustive.

Referring to FIG. 10, a mold structure 400 may be included on the first-second electrode 381. The mold structure 400 may include a first mold portion 390 and a second mold portion 395. The first mold portion 390 and the second mold portion 395 may include an organic insulating material. First, in the upper side of the first substrate 300, there may be disposed a mask M including an opening pattern. Next, the space S2 inside the first-second electrode 381 may be filled with a first insulating material, and then a curing process may be performed to form the first mold portion 390. The first mold portion 390 may have the same height as the first-second electrode 381. The first mold portion 390 may have a hemispherical shape as it fills the space S2 inside the first-second electrode 381. For example, the first mold portion 390 may have a concave hemispherical shape with one flat surface.

Next, a second insulating material may be applied on the first mold portion 390, and a curing process may be performed to form the second mold portion 395. The second mold portion 395 may have a convex hemispherical shape with one flat surface. The flat surface of the second mold portion 395 may be in contact with the flat surface of the first mold portion 390. Thereby, the mold structure 400 including the first mold portion 390 and the second mold portion 395 may have a sphere shape.

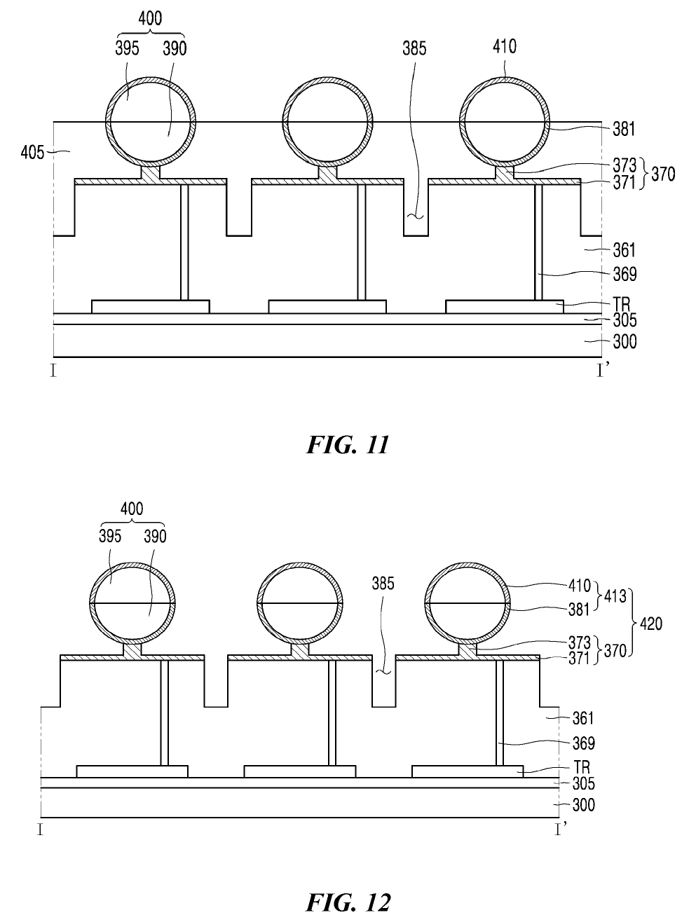

Referring to FIG. 11, a barrier film 405 is formed on the first substrate 300. The barrier film 405 may be disposed on the insulating structure 361 including the trench 385. For example, the barrier film 405 may be formed to cover the first-first electrode 370 and the first-second electrode 381. The barrier film 405 may include an organic insulating material. For example, the organic insulating material may include, but is not limited to, a photoresist material. The barrier film 405 may expose the second mold portion 395. A material layer for the first-third electrode is formed on the barrier film 405 and the second mold portion 395. In a subsequent step, a patterning process is performed on the material layer for the first-third electrode to form the first-third electrode 410 covering the outer surface of the second mold portion 395. The first-third electrode 410 may be made of the same material as the first-first electrode 370.

Referring to FIG. 12, the barrier film 405 is removed through a wet strip process. Thereby, the first-first electrode 370, the first-second electrode 381, and the trench 385, which had been covered with the barrier film 405, can be exposed. For example, the wet strip process may be performed using a stripping solution containing sulfuric acid (H2SO4) or hydrogen peroxide (H2O2). Thereby, the first electrode 420 including the first-first electrode 370, the first-second electrode 381, and the first-third electrode 410 can be formed. The first electrode 420 may be referred to as an anode electrode or pixel electrode.

The first electrode 420 may be implemented as the sphere-shaped structure 413 by the concave hemispherical first-second electrode 381 and the convex hemispherical first-third electrode 410 in contact with the first-second electrode 381.

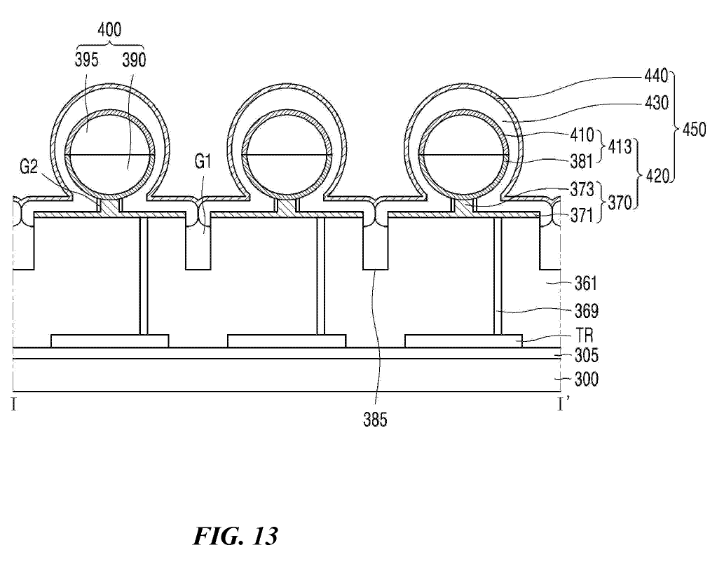

Referring to FIG. 13, on a first electrode 420 the light-emitting layer 430 may be disposed. The light-emitting layer 430 may be configured with an organic material. For example, the light-emitting layer 430 may include an organic material that emits other color light than white light. For example, the light-emitting layer 430 may be an organic material that emits blue light.

The light-emitting layer 430 may be disposed to cover the sphere-shaped structure 413 including the first-third electrode 410 and the first-second electrode 381 and extend on the upper surface of the first-first electrode 370.

The light-emitting layer 430 may be formed continuously without any disconnection on the first-first electrode 370, the first-second electrode 381, and the first-third electrode 410. To this end, the first substrate 300 may be seated on a stage of an organic material deposition equipment, and the organic material may be deposited in a state where the stage is tilted at a first angle as measured based on the plane of the first substrate 300 so that the organic material can be deposited on the first-first electrode 370. Next, the organic material may be deposited in a state where the stage is tilted at a second angle different from the first angle so that the organic material can be deposited on the first-second electrode 381 and the first-third electrode 410. That is, by depositing the organic material in a state where the stage is tilted at the first angle and the second angle, the organic material can be deposited without any disconnection up to the lower surface of the first-second electrode 381 having a hemispherical shape.

Additionally, in order for the light-emitting layer 430 to be formed continuously without any disconnection across the plurality sub-pixels, the thickness of the second portion 373 of the first-first electrode 370, which protrudes from the first portion 371, may be smaller than the thickness of the light-emitting layer 430 disposed on the first portion 371 of the first-first electrode 370.

The light-emitting layer 430 may be disposed on the entire surface of the display area DA. The light-emitting layer 430 may be disposed on the upper edges of the trench 385 between adjacent sub-pixels. Thereby, within the trench 385 a first gap G1 may be formed. Additionally, the light-emitting layer 430 may form a second gap G2 on the side surface of the second portion 373 of the first-first electrode 370; however, this is not exhaustive. For example, the light-emitting layer 430 may be filled so as to come into contact with the side surface of the second portion 373 of the first-first electrode 370. Similarly, as an example, the light-emitting layer 430 may be filled so as to come into contact with the bottom surface of the trench 385. Since the light-emitting layer 430 is formed to conform to the shape of the first electrode 420, it may include a convex spherical shape.

The second electrode 440 may be disposed on the light-emitting layer 430. The second electrode 440 may function as a cathode electrode. The second electrode 440 may be formed across the entire surface of the first substrate 300 so as to be commonly connected to the light-emitting layer 430 formed in all the pixels. Therefore, the second electrode 440 may also be referred to as a common electrode. In a top-emitting type display panel in which light emitted from the light-emitting layer 430 is emitted upward, the second electrode 440 may be made of a transparent conductive material such as indium tin oxide (ITO) or indium zinc oxide (IZO).

Since the second electrode 440 is disposed to conform to the shape of the first electrode 420 and the light-emitting layer 430, it may include a convexly protruding shape. The light-emitting element 450 may include and be configured with the first electrode 420, the light-emitting layer 430, and the second electrode 440.

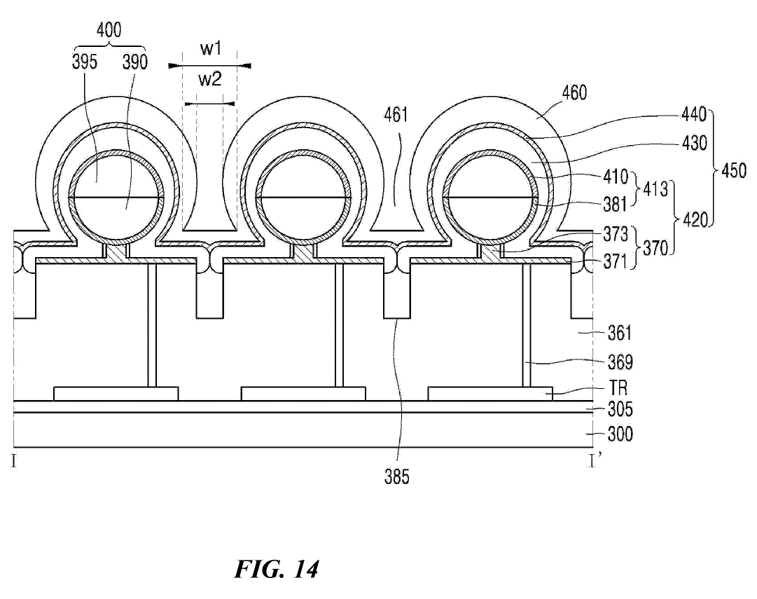

Referring to FIG. 14, the encapsulation layer 460 may be formed on the second electrode 440. The encapsulation layer 460 can reduce the penetration of moisture or foreign substances from the outside into the light-emitting element 450. The encapsulation layer 460 may include an inorganic insulating material. The encapsulation layer 460 may be disposed on the entire surface of the first substrate 300 to conform to the shape of the second electrode 440. Thereby, the encapsulation layer 460 may be disposed in a convexly protruding shape. Therefore, the encapsulation layer 460 may include a spacing space 461 disposed between adjacent sub-pixels.

The spacing space 461 may include a first width w1 and a second width w2. The first width w1 and the second width w2 may be different from each other in size. The first width w1 may be greater than the second width w2. The first width w1 of the spacing space 461 may be disposed on the side close to the first substrate 300. For example, the first width w1 of the spacing space 461 may be the width between the most concave portions of the first-second electrodes 381 disposed in each of the adjacent sub-pixels. The second width w2 of the spacing space 461 may be the width between the most protruding portions of the sphere-shaped structures 413 of the first electrodes 420 disposed in each of the adjacent sub-pixels, and thus be smaller than the first width w1. As an example, the first width w1 may be the width of the bottom surface of the spacing space 461, and the second width w2 may be the narrowest width of the spacing space 461. As an example, the bottom surface of the spacing space 461 may be lower than the boundary between the first-second electrode 381 and the first-third electrode 410, without being limited thereto. As an example, the second width w2 may be the width of the spacing space 461 at the level corresponding to the boundary between the first-second electrode 381 and the first-third electrode 410, without being limited thereto.

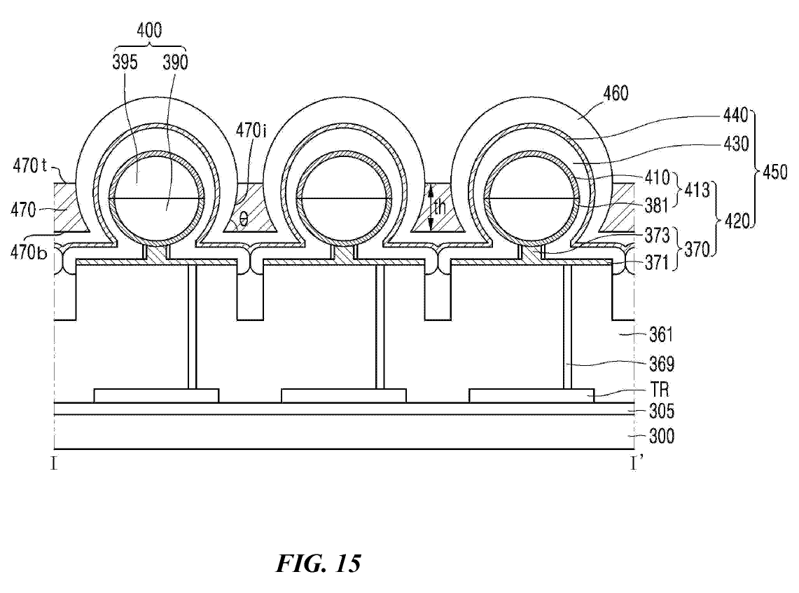

Referring to FIGS. 14 and 15, the first reflective pattern 470 may be formed to fill a portion of the spacing space 461.

The first reflective pattern 470 may include a bottom surface 470b, an upper surface 470t opposite to the bottom surface 470b, and inclined surfaces 470i each of which extends from the bottom surface to the upper surface 470t. The first reflective pattern 470 may be configured to have a first thickness th with which the upper surface 470t is disposed at a position lower than the most protruding portion of the encapsulation layer 460 and higher than the first-second electrode 381.

The bottom surface 470b of the first reflective pattern 470 may have the same size as the first width w1 of the spacing space 461 (see FIG. 14). The upper surface 470t of the first reflective pattern 470 may have the same size as the second width w2 of the spacing space 461 (see FIG. 14). The inclined surface 470i of the first reflective pattern 470 may have a slope at which it is inclined forming a first inclined angle θ with respect to the bottom surface 470b. For example, the first inclined angle θ may be an acute angle less than 90 degrees. The first reflective pattern 470 may include a metal material having a high reflectivity. For example, the first reflective pattern 470 may include silver (Ag), a silver alloy, aluminum (Al), or an aluminum alloy.

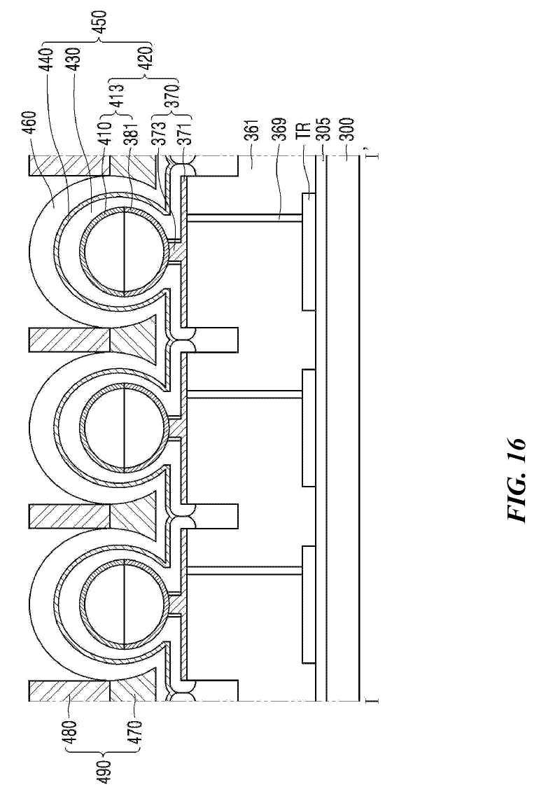

Referring to FIG. 16, the reflective structure 490 may be configured by disposing the second reflective pattern 480 on the first reflective pattern 470. The second reflective pattern 480 may be disposed on the upper surface 470t of the first reflective pattern 470 (see FIG. 15). The second reflective pattern 480 may include a bottom surface in contact with the upper surface 470t of the first reflective pattern 470, an upper surface opposite to the bottom surface, and side surfaces each of which extends from the bottom surface to the upper surface. In an example, the second reflective pattern 480 may have the bottom and upper surfaces of the same width. For example, the width of each of the bottom surface and the upper surface of the second reflective pattern 480 may be the same size as the second width w2 of the upper surface 470t of the first reflective pattern 470. Thereby, the side surface between the bottom surface and the top surface of the second reflective pattern 480 may be configured at a 90 degree angle with respect to them. The second reflective pattern 480 may include a metal material having a high reflectivity. For example, the second reflective pattern 480 may include a metal material having the same reflectivity as the first reflective pattern 470.

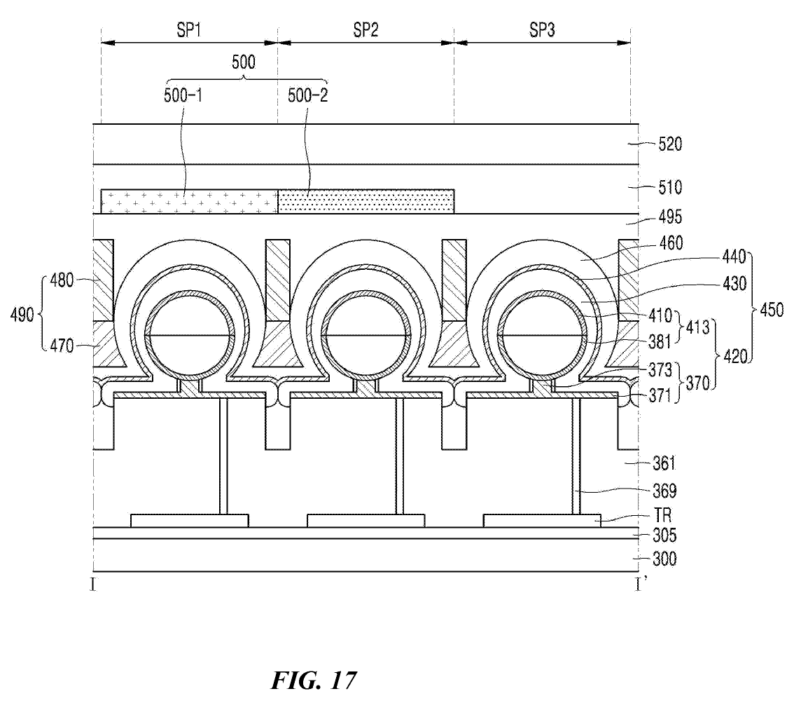

Referring to FIG. 17, the planarization layer 495 may be formed on the reflective structure 490 and the encapsulation layer 460. The encapsulation layer 495 serves to planarize the steps created by the reflective structure 490, the light-emitting element 450, and the encapsulation layer 460. The planarization layer 495 may be a single layer or multi-layered. The planarization layer 495 may include, but is not limited to, one or more of organic insulating materials such as acrylic resin, epoxy resin, phenolic resin, polyamide resin, and polyimide resin.

The plurality of color conversion layers 500 may be disposed on the planarization layer 495. On the color conversion layer 500 the protective layer 510 and the second substrate 520 may be disposed.

The plurality of color conversion layers 500 may be layers, each of which converts light emitted to the outside from each sub-pixel SP1, SP2 into light of a color corresponding to each sub-pixel SP1, SP2. For example, the plurality of color conversion layers 500 may include the first color conversion layer 500-1 and the second color conversion layer 500-2.

The light-emitting elements 450 of the first sub-pixel SP1 to the third sub-pixel SP3 may output blue light. The blue light output from the light-emitting element 450 may be converted into light of the first color while passing through the first color conversion layer 500-1 in the first sub-pixel SP1, and the converted light may be emitted to the outside through the second substrate 520. For example, the light of the first color may be red light. Additionally, the blue light output from the light-emitting element 450 may be converted into light of the second color while passing through the second color conversion layer 500-2 in the second sub-pixel SP2, and the converted light may be emitted to the outside through the second substrate 520. For example, the light of the second color may be green light.

The first color conversion layer 500-1 may include a first quantum dot that converts blue light into red light which is the light of the first color corresponding to the first sub-pixel SP1. The second color conversion layer 500-2 may include a second quantum dot that converts blue light into green light which is the light of the second color corresponding to the second sub-pixel SP2. The first quantum dot or the second quantum dot may include quantum dots of different types or quantum dots of different sizes so that each sub-pixel SP1, SP2 can convert light of the same color into light of a different color. For example, the first quantum dot or the second quantum dot may include, but is not limited to, a multilayer quantum dot with a core/shell structure or a single-layer quantum dot, which includes at least one of a III-V group semiconductor nanocrystal and a II-VI group semiconductor nanocrystal.

The third sub-pixel SP3 may have no color conversion layer because the blue light must be emitted to the outside.

The protective layer 510 may be disposed on the plurality of color conversion layers 500 and the planarization layer 495. The protective layer 510 may also be referred to as an overcoat layer. Since no color conversion layer is disposed at a position corresponding to the third sub-pixel SP3, the planarization layer 495 may be exposed. For this reason, the protective layer 510 may be disposed to be in contact with the planarization layer 495 in the third sub-pixel SP3.

The second substrate 520 may be disposed on the protective layer 510. The second substrate 520 may display an image emitted from the light-emitting elements 450. The second substrate 520 may include glass or a plastic film.

In an embodiment of the present disclosure, the brightness of the display panel can be improved by emitting light through a sphere-shaped first electrode in each of a plurality of sub-pixels in all directions of the surface of the sphere. That is, the brightness of the display apparatus can be improved by increasing the light-emitting surface area for light generated from the light-emitting element.

Further, the light collection efficiency can be improved by reducing or preventing the mixing of light and the light leakage phenomenon in the downward direction of the sphere-shaped first electrode with the use of the reflective structure disposed between adjacent sub-pixels. Additionally, the sub-pixels can be distinguished from each other by the respective the first-first electrodes of first electrodes. Thereby, banks for distinguishing sub-pixels from each other can be omitted, thus reducing or preventing a reduction in aperture ratio. As a result, the aperture ratio of each sub-pixel can be improved.

Additionally, it can improve the color reproducibility by allowing each sub-pixel in which the light-emitting element including the sphere-shaped structure is disposed to emit blue light and controlling the color emitted from the each sub-pixel via the color conversion layer.

Therefore, according to an embodiment of the present disclosure, it is possible to provide a display apparatus capable of realizing high color reproducibility and high brightness, thereby enabling the operation at low power and the reduction in power consumption.

Meanwhile, the arrangement shape, arrangement order, and arrangement direction of sub-pixels SP1, SP2, SP3 may be changed in various ways. For example, the sub-pixels SP1, SP2, SP3 may be arranged in a honeycomb shape, or to be staggered with respect to each other. Hereinafter, description will be given with reference to drawings.

FIGS. 18 and 19 are plan views showing pixels according to other embodiments of the present disclosure. For convenience of explanation, only the first electrode 420 and trench 385 are illustrated in FIGS. 18 and 19.

Referring to FIG. 18, a plurality of sub-pixels SP1, SP2, SP3 constituting each of a plurality of pixels P may be arranged on the display area DA. One unit pixel P may be constituted with three sub-pixels SP1, SP2, SP3. For example, one unit pixel P may include a first sub-pixel SP1, a second sub-pixel SP2, and a third sub-pixel SP3. The first to third sub-pixels SP1, SP2, SP3 may each emit light of a different color. The first sub-pixel SP1 may emit red light, the second sub-pixel SP2 may emit green light, and the third sub-pixel SP3 may emit blue light.

Along the nth row (n is a natural number) of the display area DA, sub-pixels SP1, SP2, SP3 respectively emitting light of different colors may be repeatedly arranged in the first direction. The first direction may be horizontal, X-axis, or row direction. Along the n+1th row n is a natural number of the display area DA spaced apart from the nth row, sub-pixels SP1, SP2, SP3 respectively emitting light of different colors may be repeatedly arranged in the first direction.

Each of the sub-pixels SP1, SP2, SP3 may include the first-first electrode 370 including the first portion 371 and the second portion 373. Adjacent sub-pixels SP1, SP2, SP3 may be disposed in a state where the first-first electrodes 370 are spaced apart from each other with the trench 385 interposed therebetween. Accordingly, the sub-pixels SP1, SP2, SP3 can be distinguished from each other by the trenches and the first-first electrodes 370 disposed to be spaced apart from each other.

According to an embodiment of the present disclosure, the first electrode 420 may be implemented as the sphere-shaped structure 413 by the concave hemispherical first-second electrode 381 and the convex hemispherical first-third electrode 410 combined with the first-second electrode 381. Accordingly, in order to dispose as many first electrodes 420 as possible within the limited space surface area of the display area DA, it is preferable that each sub-pixel be arranged in the shape of a regular polygon. For example, the shape of each sub-pixel SP1, SP2, SP3 may be implemented according to the shape of the first portion 371 of the first-first electrode 370 of the first electrode 420. For this reason, the first portion 371 of the first-first electrode 370 may be configured to have a shape of a regular polygon. In an example, the first portion 371 may have a square plate shape when viewed in a plan view.

The sub-pixels SP1, SP2, SP3 arranged in the n+1th row may be arranged by being shifted by one or half sub-pixel in the first direction, which is the horizontal direction, relative to the sub-pixels SP1, SP2, SP3 arranged in the nth row, respectively. Thereby, sub-pixels emitting light of the same color may be arranged in the downward diagonal direction, that is, the A-A' direction. However, this is not exhaustive. For example, for the sake of the efficiency of blue light, the number of sub-pixels emitting blue light may be increased.

Referring to FIG. 19, a plurality of sub-pixels SP1, SP2, SP3 may be arranged on the display area DA. The respective sub-pixels of the sub-pixels SP1, SP2, SP3 which emit light of the same color may be arranged in the second direction, which is the column direction. For example, the respective first sub-pixels SP1 may be arranged in the same column. The respective second sub-pixels SP2 may be arranged in the same column. The respective third sub-pixels SP3 may be arranged in the same column.

Each of the sub-pixels SP1, SP2, SP3 may include the first-first electrode 370 including the first portion 371 and the second portion 373. Adjacent sub-pixels SP1, SP2, SP3 may be disposed in a state where the first-first electrodes 370 are spaced apart from each other with the trench 385 interposed therebetween. Accordingly, the sub-pixels SP1, SP2, SP3 can be distinguished from each other by the trenches and the first-first electrodes 370 disposed to be spaced apart from each other.

Since the first electrode 420 according to an embodiment of the present disclosure is implemented as the sphere-shaped structure 413, it may include the first portion 371 of the first-first electrode 370, which has a regular polygon shape, in order to dispose as many first electrodes 420 as possible within a limited surface area of the display area DA. In an example, the first portion 371 of the first-first electrode 370 may have a regular hexagonal plate shape when viewed in a plan view. The sub-pixels emitting light of different colors may be arranged diagonally. However, this is not exhaustive. For example, for the sake of the efficiency of blue light, the number of sub-pixels emitting blue light may be increased.

Since the first electrode 420 of the light-emitting element according to an embodiment of the present disclosure includes the first portion 371 of the first-first electrode 370, which has a regular polygon shape, it is possible to dispose, within a limited surface area of the display area DA, as many first electrodes 420 as possible, each of which includes the sphere-shaped structure 413.

While the embodiments of the present disclosure have been described in detail with reference to the accompanying drawings, it should be understood by a person skilled in the art that the present disclosure is not necessarily limited to the above embodiments, and the above embodiments can be practiced in various modified forms without departing from the technical idea of the present disclosure. Accordingly, the embodiments disclosed in the present disclosure are not intended to limit the technical idea of the present disclosure but to explain the technical idea of the present disclosure, and the scope of the technical idea of the present disclosure is not limited by these embodiments. Therefore, it should be understood that the embodiments described above are given only as an example in all respects but not for the purpose of limiting the disclosure.

What is claimed is:

1. A display apparatus comprising:
a first substrate including a plurality of sub-pixels;
a plurality of light-emitting elements disposed respectively in the plurality of sub-pixels; and
a reflective structure between adjacent light-emitting elements from the plurality of light-emitting elements,
wherein each of the plurality of light-emitting elements includes a sphere-shaped structure.

2. The display apparatus of claim 1, wherein each of the plurality of light-emitting elements includes:
a first electrode;
a light-emitting layer on the first electrode; and
a second electrode on the light-emitting layer,
wherein the first electrode includes the sphere-shaped structure.

3. The display apparatus of claim 2, wherein the first electrode includes:
a first-first electrode disposed corresponding to a respective sub-pixel;
a first-second electrode on the first-first electrode; and
a first-third electrode on the first-second electrode,
wherein the first-second electrode includes a first space having a concave hemispherical shape concave toward the first-first electrode , and the first-third electrode includes a second space having a convex hemispherical shape convex opposite to the first-first electrode.

4. The display apparatus of claim 3, wherein the first-first electrode includes a first portion disposed corresponding to the respective sub-pixel and a second portion protruding from the first portion, and
wherein the first-second electrode is disposed on the second portion of the first-first electrode.

5. The display apparatus of claim 4, wherein a thickness of the second portion of the first-first electrode is smaller than a thickness of the light-emitting layer.

6. The display apparatus of claim 3, wherein the first space and the second space are filled with an organic insulating material and are sphere-shaped.

7. The display apparatus of claim 4, wherein the light-emitting layer is continuously disposed on the first-first electrode, the first-second electrode, and the first-third electrode.

8. The display apparatus of claim 7, wherein the light-emitting layer forms a gap on a side surface of the second portion of the first-first electrode.

9. The display apparatus of claim 4, wherein the first portion has a flat plate shape, and the second portion has a pillar shape protruding from an upper surface of the first portion in the central portion of the first portion.

10. The display apparatus of claim 3, wherein an end portion of the first-second electrode is in contact with an end portion of the first-third electrode, and the first-second electrode and the first-third electrode seal the first space and the second space.

11. The display apparatus of claim 3, wherein the first-second electrode include a material having a relatively faster etching rate than that of the first-first electrode and the first-third electrode.

12. The display apparatus of claim 2, wherein the light-emitting layer includes an organic material generating blue light.

13. The display apparatus of claim 1, further comprising a reflective structure disposed between adjacent light-emitting elements.

14. The display apparatus of claim 13, further comprising:
an encapsulation layer on the plurality of light-emitting elements;
a planarization layer on the encapsulation layer;
a color conversion layer on the planarization layer;
a protective layer on the color conversion layer; and
a second substrate on the protective layer.

15. The display apparatus of claim 14, wherein the color conversion layer overlaps with one or more of the plurality of sub-pixels.

16. The display apparatus of claim 1, further comprising:
an encapsulation layer disposed on the light-emitting element,
wherein the encapsulation layer includes a spacing space between adjacent sub-pixels and the reflective structure is in the spacing space.

17. The display apparatus of claim 16, wherein the reflective structure includes:
a first reflective pattern that fills a portion of the spacing space; and
a second reflective pattern having one surface in contact with an upper surface of the first reflective pattern.

18. The display apparatus of claim 17, wherein the first reflective pattern includes:
a bottom surface of a first width;
an upper surface opposite to the bottom surface, the upper surface having a second width that is smaller than the first width; and
an inclined surface extending from the bottom surface to the upper surface,
wherein the inclined surface has a slope at which it is inclined such that a first inclined angle is formed with respect to the bottom surface.

19. The display apparatus of claim 18, wherein the first inclined angle includes an acute angle that is less than 90 degrees.

20. The display apparatus of claim 19, wherein the second reflective pattern includes:
a bottom surface of a first width in contact with the upper surface of the first reflective pattern;
an upper surface opposite to the bottom surface, the upper surface having a second width that is equal to the first width; and
a side surface extending from the bottom surface to the upper surface,
wherein the side surface has a 90 degree angle with respect to the bottom surface.
